(19) United States
(12) Patent Application Publication
(10) Pub. No.: US 2022/0239268 A1
(43) Pub. Date: Jul. 28, 2022

(54) ADAPTIVE VOLUME CONTROL BASED ON USER ENVIRONMENT

(71) Applicant: Rovi Guides, Inc., San Jose, CA (US)

(72) Inventors: Rohit Dhiman, Haridwar (IN); Ashish Gupta, Bangalore (IN); Vaibhav Gupta, Bangalore (IN); Senthil Kumar Karuppasamy, Bangalore (IN)

(21) Appl. No.: 17/160,532

(22) Filed: Jan. 28, 2021

(51) Int. Cl. H03G 3/32; H04N 21/45; H04N 21/442; H04N 21/485

(52) U.S. Cl. CPC H03G 3/32; H04N 21/4852; H04N 21/44218; H04N 21/4532

(57) ABSTRACT

Systems and methods are provided herein for adaptively controlling the output volume level of audio content being played in a media presentation environment based on a change in the number of users in the media presentation environment. In response to detecting a change in the number of users, a stored output volume adjustment value corresponding to the detected change is retrieved and used to automatically adjust the output volume level of the audio content. In response to receiving a volume change request from a user within a predetermined time after the automatic adjustment of the output volume, the output volume level is adjusted to the user requested value and the stored output volume adjustment value is adjusted based on a difference between the automatically adjusted output volume level and the user-adjusted output volume level.

### BACKGROUND

The present disclosure is directed to systems and methods for adaptively controlling the output volume level of audio content being played in a media presentation environment, and more particularly, for adaptively controlling the output volume level of audio content being played in a media presentation environment based on a change in the number of users in the media presentation environment.

### SUMMARY

While a user is consuming audio content in a media presentation environment (e.g., living room, media room), changes in the media presentation environment (e.g., people entering/leaving the media presentation environment, background noise) may interfere with the user's listening experience. For example, if background noise increases or if people enter the media presentation environment, the user may not be able to hear the audio content. Similarly, if the background noise decreases or if people leave the media presentation environment, the audio content may be too loud for the user. In some cases, the user may manually adjust the output volume level of the audio content in response to changes in the media presentation environment. However, if the user adjusts the output volume level every time the media presentation environment changes, a significant amount of time and processing resources may be wasted.

In one approach, a system may monitor background noise in a media presentation environment and automatically adjust the output volume level of the audio content based on changes in the background noise. For example, if the background noise increases, the system may increase the output volume level of the audio content. However, in this approach, because the output volume level is adjusted based on background noise, it may be difficult to account for other changes in the media presentation environment that interfere with the user's listening experience. For example, users in the media presentation environment may absorb sound energy and change the way sound propagates through the media presentation environment. Thus, if the number of users in the media presentation environment changes, the user's listening experience may be negatively affected. Additionally, unlike background noise, it may be difficult for the user to recognize that a change in the number of users in the media presentation environment affects their listening experience. Additionally, because different users may have different preferences (e.g., based on hearing, output volume preferences), it may be difficult to adjust the output volume level to optimize a particular user's listening experience.

Accordingly, to solve these problems, systems and methods are provided for adaptively controlling the output volume level of audio content being played in a media presentation environment based on a change in the number of users in the media presentation environment. In particular, a media player application may play, via a computing device in the media presentation environment, audio content at a first output volume level. The media player application may monitor the media presentation environment and detect a change in a number of users in the media presentation environment. In response to detecting the change in the number of users in the media presentation environment, the media player application may retrieve a stored output volume adjustment value corresponding to the detected change in the number of users in the media presentation environment, and automatically adjust the first output volume level to a second output volume level, based on the retrieved output volume adjustment value. After automatically adjusting the output volume, the media player application may receive a volume change request from a user in the media presentation environment to adjust the second output volume level to a third output volume level. In response to receiving the volume change request, the media player application may adjust the second output volume level to the third output volume level and determine whether the volume change request was received within a predetermined time after automatically adjusting the first output volume level to the second output volume level. In response to determining that the volume change request was received within the predetermined time, the media player application may update the stored output volume adjustment value corresponding to the detected change in the number of users in the media presentation environment, based on a difference between the second output volume level and the third output volume level. This solves the problem of a system that does not automatically adjust the output volume level based on a particular user's preferences, by optimizing an output volume level profile based on user feedback.

In some embodiments, the media player application may detect noise in the media presentation environment. The media player application may automatically adjust the first output volume level to the second output volume level further based on the detected noise in the media presentation environment.

In some embodiments, when updating the stored output volume adjustment value corresponding to the detected change in the number of users in the media presentation environment, the media player application may update a plurality of stored output volume adjustment values, each corresponding to a respective change in a number of users in the media presentation environment, based on the difference between the second output volume level and the third output volume level. The stored output volume adjustment value corresponding to the detected change in the number of users in the media presentation environment may be one of the plurality of stored output volume adjustment values.

In some embodiments, when the detected change in the number of users in the media presentation environment is an increase in the number of users, the media player application, when automatically adjusting the first output volume level to the second output volume level, may increase the first output volume level to the second output volume level.

In some embodiments, when the detected change in the number of users in the media presentation environment is a decrease in the number of users, the media player application, when automatically adjusting the first output volume level to the second output volume level, may decrease the first output volume level to the second output volume level.

In some embodiments, the media player application may determine a user profile of a user in the media presentation environment, and when updating the stored output volume adjustment value corresponding to the change in the number of users in the media presentation environment, may update a stored output volume adjustment value in the determined user profile.

In some embodiments, the determined user profile may be associated with the user from which the volume change request was received.

In some embodiments, when the third output volume level is less than the second output volume level, the media player application, when updating the stored output volume adjustment value, may decrease the stored output volume adjustment value. When the third output volume level is greater than the second output volume level, the media player application, when updating the stored output volume adjustment value, may increase the stored output volume adjustment value.

In some embodiments, the media player application, in response to automatically adjusting the first output volume level to the second output volume level, may generate for output a notification that an output volume level has been changed based on the detected change in the number of users in the media presentation environment.

In some embodiments, the media player application, when detecting the change in the number of users in the media presentation environment, may detect a first change in the number of users in the media presentation environment. In some embodiments, the media player application may detect a second change in the number of users in the media presentation environment. In some embodiments, in response to detecting the second change in the number of users in the media presentation environment, the media player application may retrieve the updated stored output volume adjustment value corresponding to the detected first change in the number of users in the media presentation environment, and automatically adjust the third output volume level to a fourth output volume level, based on the retrieved updated stored output volume adjustment value.

### BRIEF DESCRIPTION OF THE DRAWINGS

The above and other objects and advantages of the disclosure will be apparent upon consideration of the following detailed description, taken in conjunction with the accompanying drawings, in which like reference characters refer to like parts throughout, and in which:

FIG. 1 shows an illustrative process for automatically adjusting an output volume level of audio content when a number of users in a media presentation environment changes, and selectively updating a stored output volume adjustment value based on user feedback, in accordance with some embodiments of the present disclosure;

FIG. 2 shows a graph of a plurality of output volume adjustment profiles, in accordance with some embodiments of the present disclosure;

FIG. 3 provides an example screen illustrating a notification being shown after the output volume has been automatically adjusted, in accordance with some embodiments of the present disclosure;

FIGS. 4-5 describe exemplary devices, systems, servers, and related hardware for automatically adjusting an output volume level of audio content when a number of users in a media presentation environment changes, and selectively updating a stored output volume adjustment value based on user feedback, in accordance with some embodiments of the present disclosure;

FIG. 6 depicts a flowchart of illustrative steps for automatically adjusting an output volume level of audio content when a number of users in a media presentation environment changes, and selectively updating a stored output volume adjustment value based on user feedback, in accordance with some embodiments of the present disclosure; and

FIG. 7 depicts a flowchart of illustrative steps for identifying an output volume adjustment profile associated with a user in the media presentation environment, in accordance with some embodiments of the present disclosure.

### DETAILED DESCRIPTION

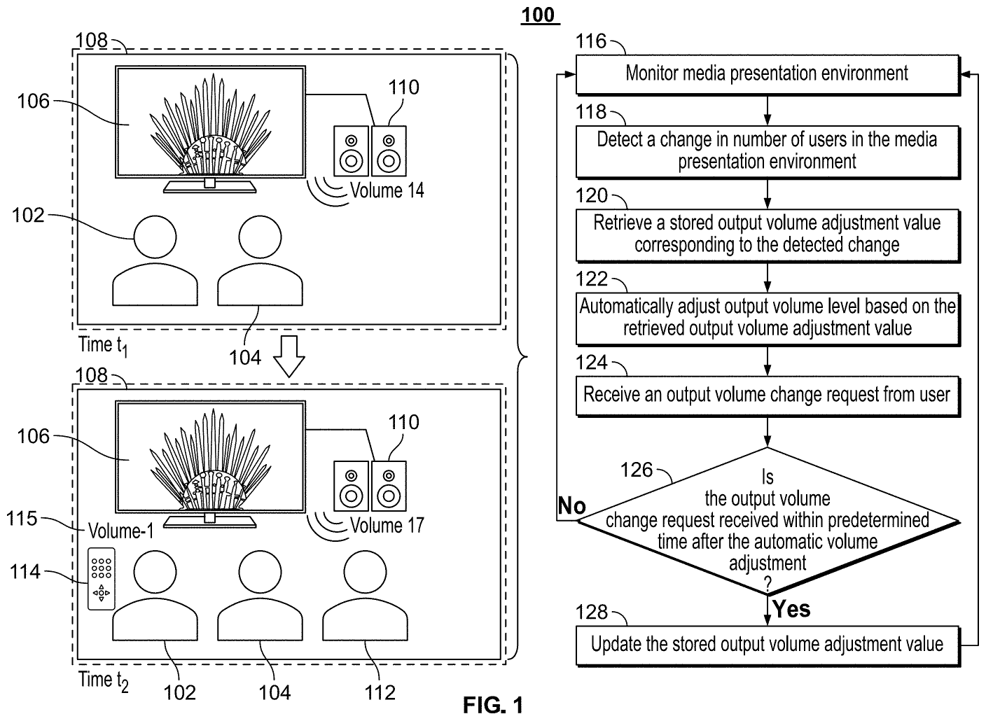

FIG. 1 shows an illustrative process 100 for automatically adjusting an output volume level of audio content when a number of users in a media presentation environment changes, and selectively updating a stored output volume adjustment value based on user feedback, in accordance with some embodiments of the present disclosure. As shown, at time t₁, a first user 102 and a second user 104 may be listening to audio content being played by a computing device 106 in a media presentation environment 108 (e.g., the room where the first user 102 and the second user 104 are listening to the audio content). For example, the audio content may be output by a speaker 110 connected to/integrated with the computing device 106. As shown, the output volume level of the computing device 106 may be set to an initial output volume level (i.e., “volume 14”) among the possible output volume levels of the computing device 106 (e.g., from volume levels zero to fifty). Although the computing device 106 is shown as a display device (e.g., a TV), the computing device 106 may be any user equipment with or without a display (e.g., a set-top box, a stereo, a laptop). In some embodiments, if the computing device 106 is a display device, the computing device 106 may play media content having a video portion and an audio portion (e.g., a movie).

At 116, while the audio content is playing, a media player application implemented on user equipment (e.g., the computing device 106) may monitor the media presentation environment 108 for the number of users in the media presentation environment 108. For example, the media player application may monitor the media presentation environment 108 using a camera in the computing device 106 and/or cameras in other user equipment (e.g., a TV, a smart home hub, the speaker 110 connected to the computing device 106, or any other device in the media presentation environment 108). However, this is only one example, and the media player application may use any other suitable hardware/techniques to detect users in the media presentation environment 108. For example, the media player application may detect users directly (e.g., by using imaging, radar, etc.) or indirectly (e.g., by detecting devices associated with the users). In some embodiments, the media player application may also monitor the media presentation environment 108 for background noise (e.g., by using a microphone in user equipment in the media presentation environment 108).

At 118, the media player application may detect a change in the number of users in the media presentation environment 108. For example, as shown, at time t₂, the media player application may detect a third user 112 enter the media presentation environment 108. In some embodiments, the media player application may maintain a table of the users in the media presentation environment 108 and update the table when a user enters or leaves the media presentation environment 108.

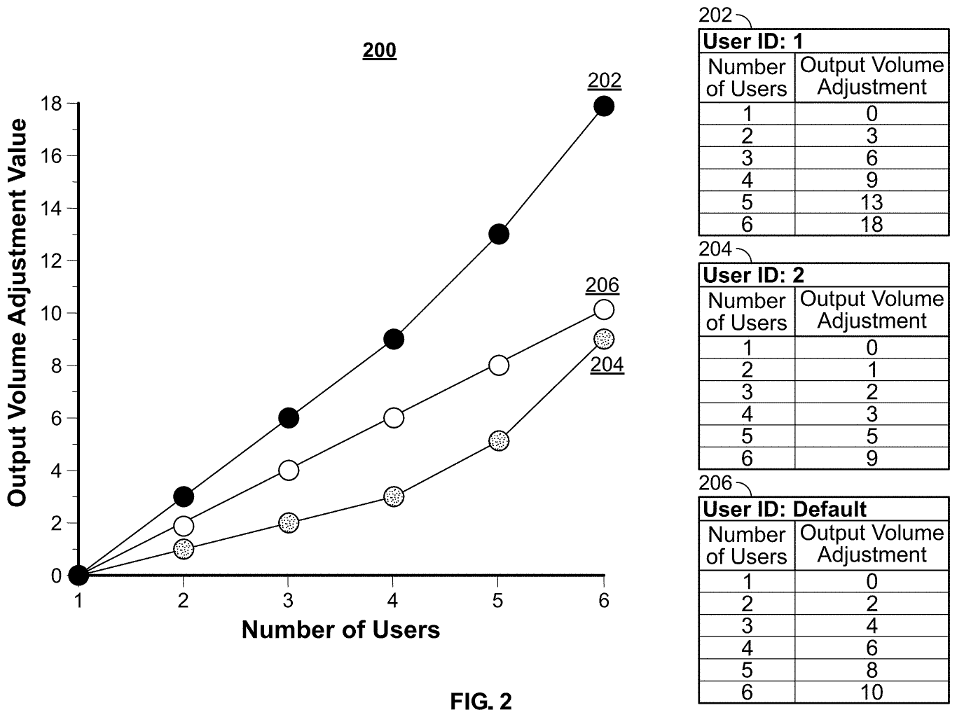

At 120, in response to detecting the change in the number of users in the media presentation environment 108 (e.g., from two to three users), the media player application may retrieve a stored output volume adjustment value corresponding to the detected change in the number of users. In some embodiments, the retrieved output volume adjustment value may be stored in a user profile associated with one of the users in the media presentation environment 108. In some embodiments, the retrieved output volume adjustment value may be one of a plurality of stored output volume adjustment values (e.g., stored together in an output volume adjustment profile), each associated with a different change in the number of users in the media presentation environment 108. A visual representation (e.g., a graph) of a plurality of output volume adjustment profiles is shown in FIG. 2.

FIG. 2 shows a graph 200 of a plurality of output volume adjustment profiles 202, 204, 205, in accordance with some embodiments of the present disclosure. As shown, two of the output volume adjustment profiles 202, 204 are associated with particular users. For example, the output volume adjustment profile 202 is associated with “User ID: 1” (e.g., the first user 102), and the output volume adjustment profile is associated with “User ID: 2” (e.g., the second user 104). In some embodiments, each of the output volume adjustment profiles 202 and 204 may be stored in a user profile associated with a particular user. As shown, the output volume adjustment profile 206 is a default profile that is not associated with a particular user (e.g., in the event that the identity of a user in the media presentation environment 108 cannot be determined). In some embodiments, in the event that the identity of a user in the media presentation environment 108 cannot be determined, the media player application may prompt the unidentified user to log in to their user profile or to create a user profile. In some embodiments, the media player application may automatically generate a new user profile for the unidentified user and assign the default output volume adjustment profile to the newly generated user profile.

In some embodiments, the output volume adjustment profiles 202 and 204 may be determined in advance (e.g., preset by the media player application), based on characteristics in a user profile (e.g., age, gender, hearing ability, etc.). As shown, the output volume adjustment values of each output volume adjustment profile 202, 204, 206 may be plotted against the number of users in the media presentation environment 108. In the illustrated example, the y-axis of the graph 200 is in the output volume increment levels associated with the computing device 106 (e.g., volume adjustable from zero to fifty), and the x-axis of the graph 200 is the number of users in the media presentation environment 108. However, this is only an example, and the graph 200 may include any axis or scales. As shown, as the number of users in the media presentation environment 108 increases, the output volume adjustment values also increase. Although the volume adjustment profiles 202, 204, 206 are shown as a table of discrete values, this is only an example, and the volume adjustment profiles may be any relationship (e.g., equation) that adjusts output volume as a function of the change of users in the media presentation environment 108.

Returning to FIG. 1, at 120, when retrieving the stored output volume adjustment value corresponding to the detected change in the number of users, the media player application may identify the users in the media presentation environment 108 and determine if an output volume adjustment profile is stored for any of the identified users. If the media player application determines that multiple output volume adjustment profiles are stored, the media player application may select one of the output volume adjustment profiles based on priority. For example, in some embodiments, the output volume adjustment profiles may have a predetermined order (e.g., set by the user). In some embodiments, the output volume adjustment profile associated with the user who initiated playback of the audio content may be assigned the highest priority. In some embodiments, a higher priority may be assigned to users who were in the media presentation environment 108 before the change in the number of users was detected. In some embodiments, a priority value may be stored in association with each output volume adjustment profile. In some embodiments, if the media player application determines that multiple users often listen to audio content together, the media player application may combine the different output volume adjustment profiles associated with the users. However, these are only examples, and the media player application may use any suitable method to select an output volume adjustment profile among a plurality of output volume adjustment profiles. As shown, the media player application may identify the first user 102 (“User ID: 1”) and select the output volume adjustment profile associated with the first user. For example, the media player application may retrieve the first output volume adjustment profile 202.

Based on the retrieved output volume adjustment profile 202, the media player application may retrieve a stored output volume adjustment value corresponding to the detected change (e.g., from two to three users). For example, as shown in FIG. 2, when the number of users changes from two to three, the corresponding output volume adjustment value is plus three (e.g., volume level associated with the updated number of users minus the volume level associated with the initial number of users). If the number of users changed from three to two, the volume adjustment value would be minus three).

At 122, the media player application may automatically adjust the output volume of the audio content based on the retrieved output volume adjustment value. For example, as shown, the media player application may automatically increase the output volume by three (i.e., from “volume 14” to “volume 17”). In some embodiments, the media player application may further adjust the output volume of the audio content based on other factors (e.g., background noise in the media presentation environment 108, a change in the background noise, etc.). For example, the media player application may further adjust the output volume to compensate for an increased or decreased level of background noise.

At 124, the media player application may receive an output volume change request 115 from a user in the media presentation environment 108. For example, the media player application may receive the output volume change request 115 from the first user 102 to decrease the automatically adjusted output volume by one (i.e., from “volume 17” to “volume 16”). The media player application may receive the output volume change request 115 through a user interface (e.g., a remote control 114).

At 126, the media player application may determine if the output volume change request 115 was received within a predetermined time after the automatic volume adjustment. In some embodiments, the media player application may record the time when the output volume is automatically updated and when the output volume change request 115 is received. If the media player application determines that the output volume change request 115 was received within the predetermined time after the automatic output volume adjustment (“Yes” at 126), the media player application may infer that the first user 108 is not satisfied by the automatic adjustment and proceed to 128 to update the stored adjustment value in the output volume adjustment profile (e.g., output volume adjustment profile 202). Otherwise, if the media player application determines that the volume change request was not received within the predetermined time after the automatic output volume adjustment (“No” at 126), the media player application may infer that the output volume change request 115 is not related to the automatic output volume adjustment, and proceed back to 116 without updating the output volume adjustment profile. The predetermined time may correspond to an average time it takes a user to change an automatically adjusted output volume (e.g., 15 seconds). In some embodiments, the predetermined time may be adjusted based on user behavior (e.g., by determining the time it normally takes for the user to adjust the volume after an automatic output volume adjustment).

At 128, the media player application may update the stored adjustment value associated with a change from two to three users, based on the difference in the automatically adjusted output volume and the output volume change request 115. For example, the media player application may update the stored adjustment value from plus three to plus two (e.g., by changing the output volume adjustment value associated with three users from six to five). In some embodiments, the media player application may update a plurality of the stored adjustment values in the output volume adjustment profile based on the updated stored adjustment value. For example, the media player application may update a plurality of the stored adjustment values by a factor of two-thirds (e.g., the updated adjustment value divided by the original adjustment value). After updating the stored adjustment value, the media player application may proceed back to 116. If the media player application detects another change in the number of users in the media presentation environment 108, the media player application may automatically adjust the output volume based on the updated adjustment values stored in the output volume adjustment profile.

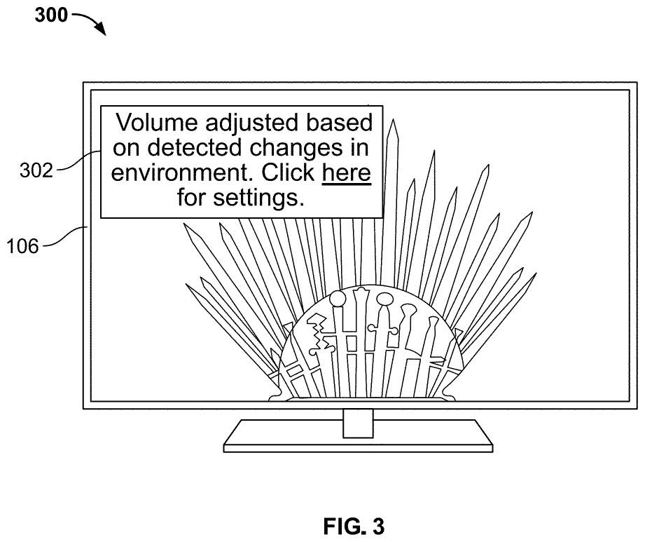

In some embodiments, the computing device 106 may output a notification (e.g., a visual notification) to inform the users that the output volume has been automatically adjusted based on a detected change in the media presentation environment 108. For example, the computing device 106 may display the notification shown in FIG. 3.

FIG. 3 provides an example screen 300 illustrating a notification 302 being shown after the output volume has been automatically adjusted, in accordance with some embodiments of the present disclosure. As shown, the notification 302 may include a link for the user to access automatic output volume adjustment settings (e.g., to modify or turn off automatic volume adjustment). In some embodiments, it may be advantageous to display the notification 302 only the first few times that the output volume is automatically adjusted, so as to inform the user of the automatic output volume adjustment without continuing to interrupt the user while audio content is being played. Although the notification 302 is shown as a visual notification, any type of notification (e.g., an audio notification) may be used.

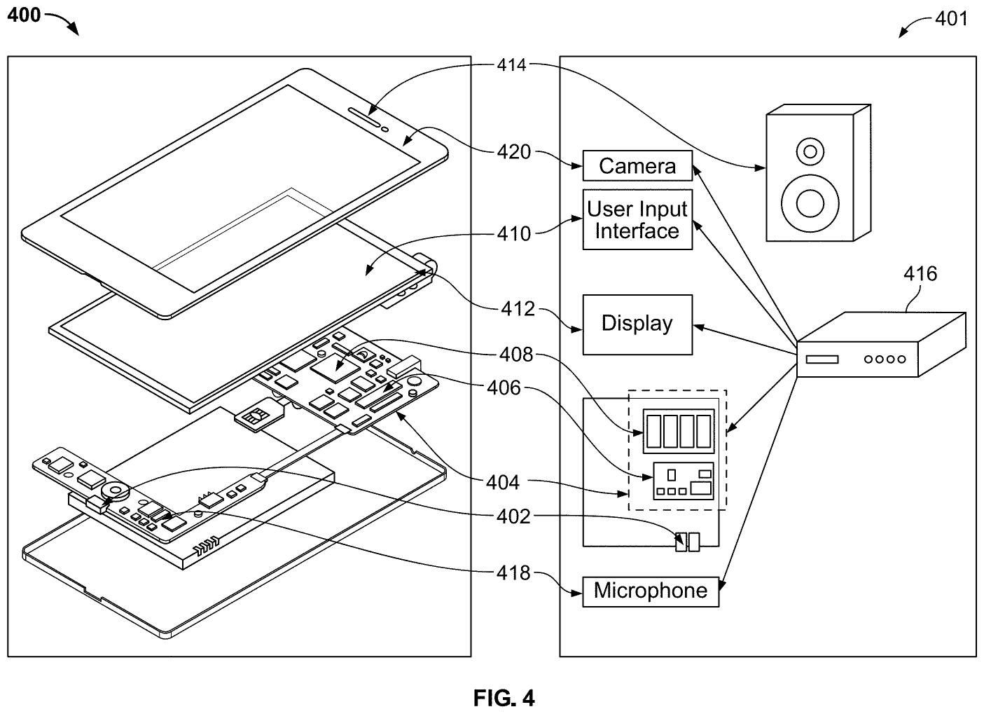

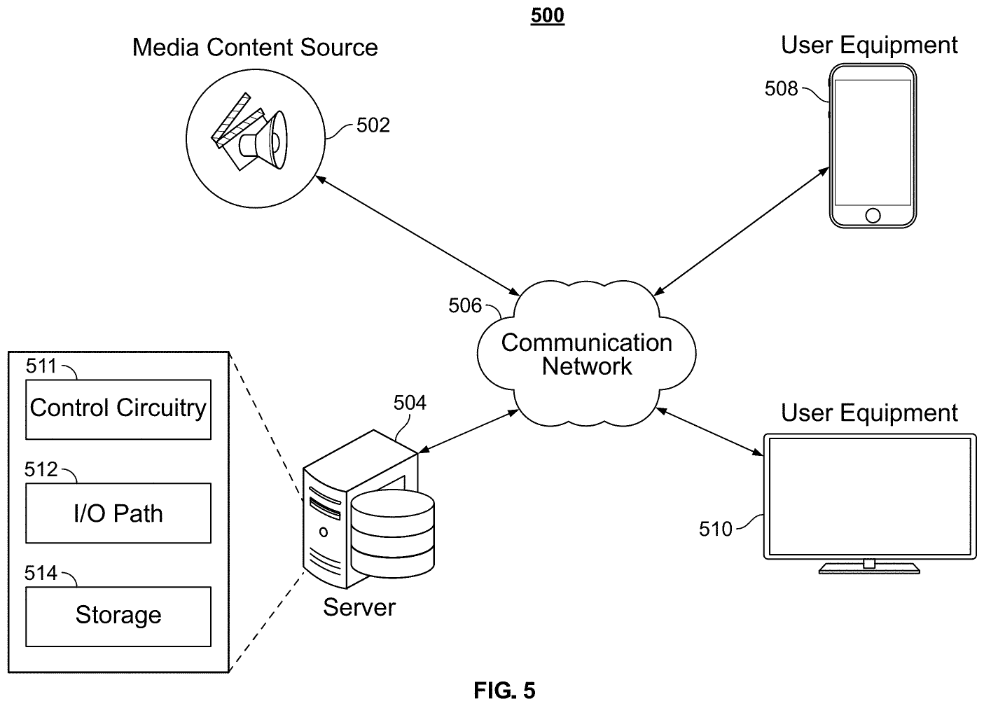

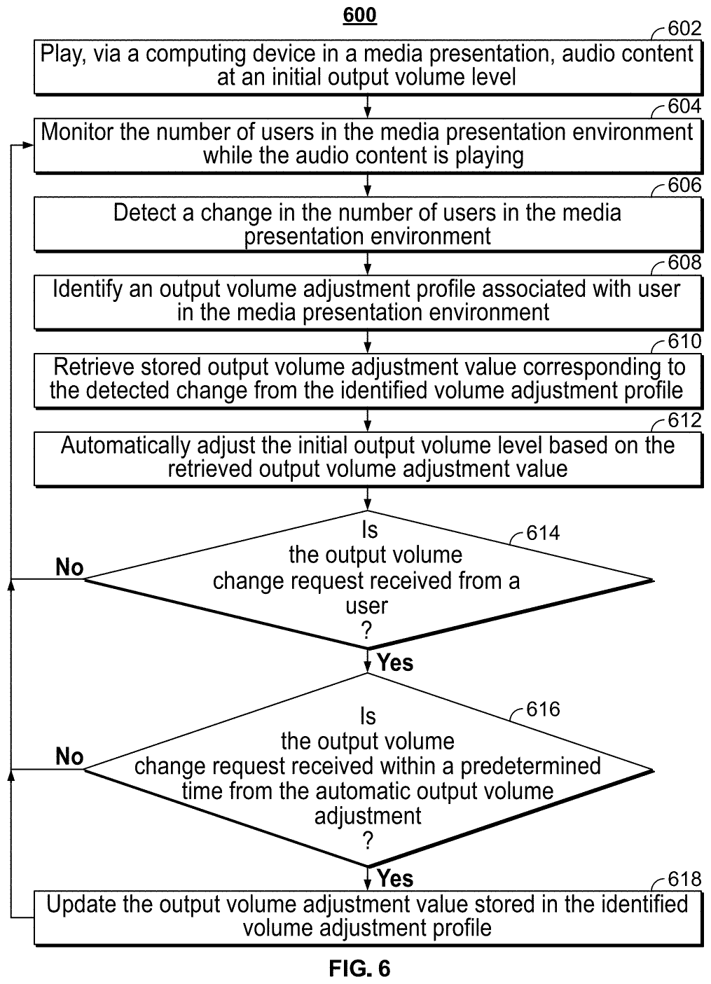

FIGS. 4-5 describe exemplary devices, systems, servers, and related hardware for automatically adjusting an output volume level of audio content when a number of users in a media presentation environment changes, and selectively updating a stored output volume adjustment value based on user feedback, in accordance with some embodiments of the present disclosure. FIG. 4 shows generalized embodiments of illustrative user equipment devices 400 and 401. For example, user equipment device 400 may be a smartphone device. In another example, user equipment system 401 may be a user television equipment system (e.g., the computing device 106). In another example, the user equipment system 401 may be a stereo or other audio playback device. The user television equipment system 401 may include a set-top box 416. The set-top box 416 may be communicatively connected to a camera 420, a microphone 418, a speaker 414, and a display 412. In some embodiments, the camera may detect users in the media presentation environment. In some embodiments, the microphone 418 may detect sound (e.g., background noise) in the media presentation environment. In some embodiments, the display 412 may be a television display or a computer display. In some embodiments, the set-top box 416 may be communicatively connected to a user input interface 410. In some embodiments, the user input interface 410 may be a remote control device (e.g., the remote control 114). The set-top box 416 may include one or more circuit boards. In some embodiments, the circuit boards may include processing circuitry, control circuitry, and storage (e.g., RAM, ROM, hard disk, removable disk, etc.). In some embodiments, the circuit boards may include an input/output path. More specific implementations of user equipment devices are discussed below in connection with FIG. 6. Each one of the user equipment device 400 and the user equipment system 401 may receive content and data via input/output (I/O) path 402. The I/O path 402 may provide content (e.g., broadcast programming, on-demand programming, Internet content, content available over a local area network (LAN) or wide area network (WAN), and/or other content) and data to control circuitry 404, which includes processing circuitry 406 and a storage 408. The control circuitry 404 may be used to send and receive commands, requests, and other suitable data using the I/O path 402. The I/O path 402 may connect the control circuitry 404 (and specifically the processing circuitry 406) to one or more communications paths (described below). I/O functions may be provided by one or more of these communications paths, but are shown as a single path in FIG. 4 to avoid overcomplicating the drawing.

The control circuitry 404 may be based on any suitable processing circuitry such as the processing circuitry 406. As referred to herein, processing circuitry should be understood to mean circuitry based on one or more microprocessors, microcontrollers, digital signal processors, programmable logic devices, field-programmable gate arrays (FPGAs), application-specific integrated circuits (ASICs), etc., and may include a multi-core processor (e.g., dual-core, quad-core, hexa-core, or any suitable number of cores) or supercomputer. In some embodiments, processing circuitry may be distributed across multiple separate processors or processing units, for example, multiple of the same type of processing units (e.g., two Intel Core i7 processors) or multiple different processors (e.g., an Intel Core i5 processor and an Intel Core i7 processor). In some embodiments, the control circuitry 404 executes instructions for a media player application stored in memory (i.e., the storage 408). Specifically, the control circuitry 404 may be instructed by the media player application to perform the functions discussed above and below. In some implementations, any action performed by the control circuitry 404 may be based on instructions received from the media player application.

In client/server-based embodiments, the control circuitry 404 may include communications circuitry suitable for communicating with a media player application server or other networks or servers. The instructions for carrying out the above-mentioned functionality may be stored on a server (which is described in more detail in connection with FIG. 5). Communications circuitry may include a cable modem, an integrated services digital network (ISDN) modem, a digital subscriber line (DSL) modem, a telephone modem, an Ethernet card, or a wireless modem for communications with other equipment, or any other suitable communications circuitry. Such communications may involve the Internet or any other suitable communication networks or paths (which is described in more detail in connection with FIG. 5). In addition, communications circuitry may include circuitry that enables peer-to-peer communication of user equipment devices, or communication of user equipment devices in locations remote from each other (described in more detail below).

Memory may be an electronic storage device provided as the storage 408 that is part of the control circuitry 404. As referred to herein, the phrase “electronic storage device” or “storage device” should be understood to mean any device for storing electronic data, computer software, or firmware, such as random-access memory, read-only memory, hard drives, optical drives, digital video recorders (DVRs, sometimes called personal video recorders, or PVRs), solid state devices, quantum storage devices, gaming consoles, gaming media, or any other suitable fixed or removable storage devices, and/or any combination of the same. The storage 408 may be used to store various types of content described herein as well as media player application data described above. For example, the storage 408 may be used to store the output volume adjustment profiles described in FIG. 2. Nonvolatile memory may also be used (e.g., to launch a boot-up routine and other instructions). Cloud-based storage, described in relation to FIG. 5, may be used to supplement the storage 408 or instead of the storage 408.

The control circuitry 404 may include video generating circuitry and tuning circuitry, such as one or more analog tuners, one or more MPEG-2 decoders or other digital decoding circuitry, high-definition tuners, or any other suitable tuning or video circuits or combinations of such circuits. Encoding circuitry (e.g., for converting over-the-air, analog, or digital signals to MPEG signals for storage) may also be provided. The control circuitry 404 may also include scaler circuitry for upconverting and downconverting content into the preferred output format of the user equipment 400. The circuitry 404 may also include digital-to-analog converter circuitry and analog-to-digital converter circuitry for converting between digital and analog signals. The tuning and encoding circuitry may be used by the user equipment device to receive and to display, to play, or to record content. The tuning and encoding circuitry may also be used to receive guidance data. The circuitry described herein, including for example, the tuning, video generating, encoding, decoding, encrypting, decrypting, scaler, and analog/digital circuitry, may be implemented using software running on one or more general purpose or specialized processors. Multiple tuners may be provided to handle simultaneous tuning functions (e.g., watch and record functions, picture-in-picture (PIP) functions, multiple-tuner recording, etc.). If the storage 408 is provided as a separate device from the user equipment device 400, the tuning and encoding circuitry (including multiple tuners) may be associated with the storage 408.

A user may send instructions to the control circuitry 404 using the user input interface 410. The user input interface 410 may be any suitable user interface, such as a remote control, mouse, trackball, keypad, keyboard, touchscreen, touchpad, stylus input, joystick, voice recognition interface, or other user input interfaces. The display 412 may be provided as a stand-alone device or integrated with other elements of each one of the user equipment device 400 and the user equipment system 401. For example, the display 412 may be a touchscreen or touch-sensitive display. In such circumstances, the user input interface 410 may be integrated with or combined with display 412. The display 412 may be one or more of a monitor, a television, a display for a mobile device, or any other type of display. A video card or graphics card may generate the output to the display 412. The video card may be any processing circuitry described above in relation to the control circuitry 404. The video card may be integrated with the control circuitry 404. Speakers 414 may be provided as integrated with other elements of each one of the user equipment device 400 and the user equipment system 401 or may be stand-alone units. The audio component of videos and other content displayed on the display 412 may be played through the speakers 414. In some embodiments, the audio may be distributed to a receiver (not shown), which processes and outputs the audio via speakers 414.

The media player application may be implemented using any suitable architecture. For example, it may be a stand-alone application wholly implemented on each one of the user equipment device 400 and the user equipment system 401. In such an approach, instructions of the application are stored locally (e.g., in the storage 408), and data for use by the application is downloaded on a periodic basis (e.g., from an out-of-band feed, from an Internet resource, or using another suitable approach). The control circuitry 404 may retrieve instructions of the application from the storage 408 and process the instructions to rearrange the segments as discussed. Based on the processed instructions, the control circuitry 404 may determine what action to perform when input is received from the user input interface 410. For example, movement of a cursor on a display up/down may be indicated by the processed instructions when the user input interface 410 indicates that an up/down button was selected.

In some embodiments, the media player application is a client/server-based application. Data for use by a thick or thin client implemented on each one of the user equipment device 400 and the user equipment system 401 is retrieved on demand by issuing requests to a server remote to each one of the user equipment device 400 and the user equipment system 401. In one example of a client/server-based guidance application, the control circuitry 404 runs a web browser that interprets web pages provided by a remote server. For example, the remote server may store the instructions for the application in a storage device. The remote server may process the stored instructions using circuitry (e.g., the control circuitry 404) and to automatically adjust an output volume level of audio content when a number of users in a media presentation environment changes, and selectively update a stored output volume adjustment value based on user feedback as discussed.

In some embodiments, the media player application is downloaded and interpreted or otherwise run by an interpreter or virtual machine (run by the control circuitry 404). In some embodiments, the media player application may be encoded in the ETV Binary Interchange Format (EBIF), received by the control circuitry 404 as part of a suitable feed, and interpreted by a user agent running on the control circuitry 404. For example, the media player application may be an EBIF application. In some embodiments, the media player application may be defined by a series of JAVA-based files that are received and run by a local virtual machine or other suitable middleware executed by control circuitry 404. In some of such embodiments (e.g., those employing MPEG-2 or other digital media encoding schemes), the media player application may be, for example, encoded and transmitted in an MPEG-2 object carousel with the MPEG audio and video packets of a program.

FIG. 5 is a diagram of an illustrative media system, in accordance with some embodiments of the disclosure. User equipment devices 508 and 510 (such as the computing device 106) may be coupled to communication network 506. The communication network 506 may be one or more networks including the Internet, a mobile phone network, mobile voice or data network (e.g., a 4G or LTE network), cable network, public switched telephone network, or other types of communication network or combinations of communication networks. Paths (e.g., depicted as arrows connecting the respective devices to the communication network 506) may separately or together include one or more communications paths, such as a satellite path, a fiber-optic path, a cable path, a path that supports Internet communications (e.g., IPTV), free-space connections (e.g., for broadcast or other wireless signals), or any other suitable wired or wireless communications path or combination of such paths. Communications with the client devices may be provided by one or more of these communications paths but are shown as a single path in FIG. 5 to avoid overcomplicating the drawing.

Although communications paths are not drawn between user equipment devices, these devices may communicate directly with each other via communications paths such as short-range communication paths, point-to-point communications paths, such as USB cables, IEEE 1394 cables, wireless paths (e.g., Bluetooth, infrared, IEEE 802-11x, etc.), or other short-range communication via wired or wireless paths. The user equipment devices may also communicate with each other directly through an indirect path via the communication network 506.

The system 500 includes a media content source 502 and a server 504. Communications with the media content source 502 and the server 504 may be exchanged over one or more communications paths but are shown as a single path in FIG. 5 to avoid overcomplicating the drawing. In addition, there may be more than one of each of the media content source 502 and the server 504, but only one of each is shown in FIG. 5 to avoid overcomplicating the drawing. If desired, the media content source 502 and the server 504 may be integrated as one source device.

In some embodiments, the server 504 may include control circuitry 511 and a storage 514 (e.g., RAM, ROM, hard disk, removable disk, etc.). The server 504 may also include an input/output path 512. The I/O path 512 may provide device information, or other data, over a local area network (LAN) or wide area network (WAN), and/or other content and data to the control circuitry 511, which includes processing circuitry, and the storage 514. The control circuitry 511 may be used to send and receive commands, requests, and other suitable data using the I/O path 512. The I/O path 512 may connect the control circuitry 511 (and specifically processing circuitry) to one or more communications paths.

The control circuitry 511 may be based on any suitable processing circuitry such as one or more microprocessors, microcontrollers, digital signal processors, programmable logic devices, field-programmable gate arrays (FPGAs), application-specific integrated circuits (ASICs), etc., and may include a multi-core processor (e.g., dual-core, quad-core, hexa-core, or any suitable number of cores) or supercomputer. In some embodiments, control circuitry 511 may be distributed across multiple separate processors or processing units, for example, multiple of the same type of processing units (e.g., two Intel Core i7 processors) or multiple different processors (e.g., an Intel Core i5 processor and an Intel Core i7 processor). In some embodiments, the control circuitry 511 executes instructions for an emulation system application stored in memory (e.g., the storage 514). Memory may be an electronic storage device provided as the storage 514 that is part of the control circuitry 511.

The server 504 may retrieve guidance data from media content source 502, process the data as will be described in detail below, and forward the data to the user equipment devices 508 and 510. The media content source 502 may include one or more types of content distribution equipment including an audio distribution facility, a television distribution facility, cable system headend, satellite distribution facility, programming sources (e.g., television broadcasters, such as NBC, ABC, HBO, etc.), intermediate distribution facilities and/or servers, Internet providers, on-demand media servers, and other content providers. NBC is a trademark owned by the National Broadcasting Company, Inc., ABC is a trademark owned by the American Broadcasting Company, Inc., and HBO is a trademark owned by the Home Box Office, Inc. Media content source 502 may be the originator of content (e.g., a television broadcaster, a Webcast provider, etc.) or may not be the originator of content (e.g., an on-demand content provider, an Internet provider of content of broadcast programs for downloading, etc.). The media content source 502 may include cable sources, satellite providers, on-demand providers, Internet providers, over-the-top content providers, or other providers of content. The media content source 502 may also include a remote media server used to store different types of content (including video content selected by a user), in a location remote from any of the client devices.

Client devices may operate in a cloud computing environment to access cloud services. In a cloud computing environment, various types of computing services for content sharing, storage or distribution (e.g., video sharing sites or social networking sites) are provided by a collection of network-accessible computing and storage resources, referred to as “the cloud.” For example, the cloud can include a collection of server computing devices (such as, e.g., server 504), which may be located centrally or at distributed locations, that provide cloud-based services to various types of users and devices connected via a network (such as the Internet) via communication network 506. In such embodiments, user equipment devices may operate in a peer-to-peer manner without communicating with a central server.

FIG. 6 depicts a flowchart of illustrative steps for automatically adjusting an output volume level of audio content when a number of users in a media presentation environment changes and selectively updating a stored output volume adjustment value based on user feedback, in accordance with some embodiments of the present disclosure. The process 600 may be executed by the control circuitry 404 (e.g., in a manner instructed to the control circuitry 404 by the media player application). The control circuitry 404 may be part of user equipment (e.g., a device that may have any or all of the functionality of the user equipment devices 508 or 510), or of a remote server separated from the user equipment by way of the communication network 506, or distributed over a combination of both. It should be noted that the process 600, or any step thereof, could be performed on, or provided by, any of the devices shown in FIGS. 1 and 3-5.

The process 600 begins at step 602, when the media player application (e.g., via the control circuitry 404) plays, via a computing device (e.g., the user equipment device 400 or the user television equipment system 401) in a media presentation environment (e.g., the media presentation environment 108), audio content at an initial output volume level.

At step 604, the media player application (e.g., via the control circuitry 404), monitors the number of users in the media presentation environment while the audio content is playing. For example, the control circuitry 404 may process signals from the camera 420 to detect users in the media presentation environment.

At step 606, the media player application (e.g., via the control circuitry 404), detects a change in the number of users in the media presentation environment. For example, the media player application may determine if a user enters or leaves the media presentation environment. In some embodiments, in order to avoid changing the output volume of the audio content too frequently, the media player application may determine if a user enters or leaves the media presentation environment for more than a predetermined time (e.g., one minute).

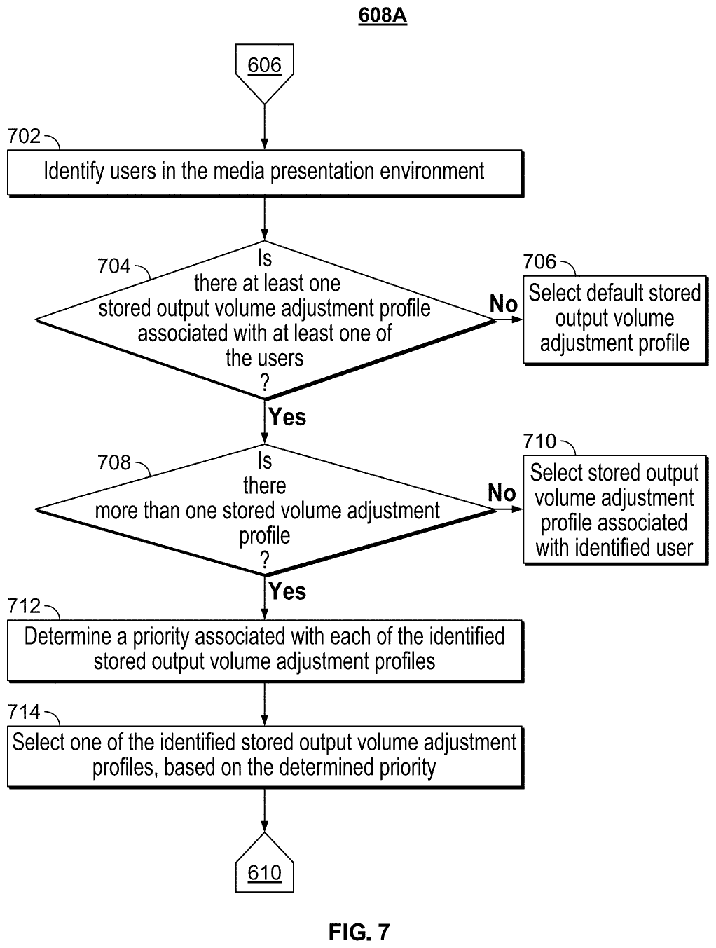

At step 608, the media player application (e.g., via the control circuitry 404), identifies an output volume adjustment profile associated with a user in the media presentation environment. For example, as described in more detail in connection with FIG. 7, the output volume adjustment profile may be selected from a plurality of output volume adjustment profiles.

At step 610, the media player application (e.g., via the control circuitry 404), retrieves a stored output volume adjustment value corresponding to the detected change from the identified output volume adjustment profile. For example, the media player application may determine a difference in output volume adjustment values corresponding to the detected change in the number of users.

At step 612, the media player application (e.g., via the control circuitry 404), automatically adjusts the initial output volume level based on the retrieved output volume adjustment value. For example, the media player application increases or decreases the initial output volume level based on the retrieved output volume adjustment value.

At step 614, the media player application (e.g., via the control circuitry 404), determines if an output volume change request is received from a user in the media presentation environment. If the control circuitry 404 determines that an output volume change request has not been received (“No” at 614), the process 600 may return back to 604 and continue to monitor the number of users in the media presentation environment. Otherwise, if the control circuitry 404 determines that an output volume change request has been received (“Yes” at 614), the process 600 may proceed to step 616.

At step 616, the media player application (e.g., via the control circuitry 404), determines if the output volume change request was received within a predetermined time from the automatic output volume adjustment. For example, the control circuitry 404 may determine whether the volume change request is within the predetermined time to determine if the output volume change request is related to the automatic volume adjustment. If the control circuitry 404 determines that the output volume change request was not received within the predetermined time from the automatic output volume adjustment (“No” at 616), the process 600 may return back to 604 and continue to monitor the number of users in the media presentation environment. Otherwise, if the control circuitry 404 determines that the output volume change request was received within the predetermined time from the automatic output volume adjustment (“Yes” at 616), the process 600 may proceed to step 618.

At step 618, the media player application (e.g., via the control circuitry 404), updates the output volume adjustment value stored in the identified volume adjustment profile. For example, the control circuitry 404 updates the output volume adjustment value stored in a storage (e.g., the storage 408), based on a difference in the automatically adjusted output volume and the output volume change request (e.g., by overwriting the previously stored output volume adjustment value). The process 600 may return back to 604 and continue to monitor the number of users in the media presentation environment. If another change in the number of users is detected, the output volume may be automatically updated based on the updated output volume adjustment value.

FIG. 7 depicts a flowchart of illustrative steps for identifying an output volume adjustment profile associated with a user in the media presentation environment, in accordance with some embodiments of the present disclosure. Process 608A is one embodiment of a method for performing step 608 of FIG. 6 and begins after step 606. At step 702, the media player application (e.g., via the control circuitry 404), identifies users in the media presentation environment. For example, the control circuitry 404 may process signals from the camera 420 to identify users in the media presentation environment (e.g., using facial recognition techniques). For example, the control circuitry 404 may compare captured images of the users in the media presentation environment to images stored in user profiles. In some embodiments, if the control circuitry 404 is unable to identify users in the media presentation environment, the control circuitry may automatically create a user profile for one or more of the users or prompt one or more of the users to create a user profile.

At step 704, the media player application (e.g., via the control circuitry 404), determines if there is at least one stored output volume adjustment profile associated with at least one of the identified users. If the control circuitry 404 determines that there is not at least one stored output volume adjustment profile associated with at least one of the identified users (or if none of the users are able to be identified) (‘No” at 704), the process 608A may proceed to step 706. Otherwise, if the control circuitry 404 determines that there is at least one stored output volume adjustment profile associated with at least one of the identified users (“Yes” at 704), the process 608A may proceed to step 708.

At step 706, the media player application (e.g., via the control circuitry 404), selects a default stored output volume adjustment profile (e.g., that is not associated with any user). In some embodiments, the control circuitry 404 may add the selected default output volume adjustment profile to a user profile associated with at least one of the identified users or to a new user profile generated for an unidentified user.

At step 708, the media player application (e.g., via the control circuitry 404), determines if there is more than one stored output volume adjustment profile associated with at least one of the identified users. If the control circuitry 404 determines that there is not more than one stored output volume adjustment profile (e.g., there is exactly one stored output volume adjustment profile) (“No” at 708), the process 608A may proceed to step 710. Otherwise, if the control circuitry 404 determines that there is more than one stored output volume adjustment profile (“Yes” at 708), the process 608A may proceed to step 712.

At step 710, the media player application (e.g., via the control circuitry 404), selects the stored output volume adjustment profile associated with the identified user.

At step 712, the media player application (e.g., via the control circuitry 404), determines priorities associated with each of the identified stored output volume adjustment profiles. For example, the media player application may determine the priorities based on a plurality of dynamic or predetermined factors (e.g., the user who initiated playback of the audio content, a predetermined assigned priority, a length of time the users have been in the media presentation environment, user settings, etc.). In some embodiments, the media player application may retrieve a priority that is stored in association with an output volume adjustment profile.

At step 714, the media player application (e.g., via the control circuitry 404), selects one of the identified stored output volume adjustment profiles, based on the determined priorities. For example, the control circuitry selects the stored output volume adjustment profile with the highest priority (e.g., the highest priority value). The process 608A then continues with step 610, in which the media player application uses the selected output volume adjustment profile to automatically adjust the output volume of the audio content.

The processes discussed above are intended to be illustrative and not limiting. One skilled in the art would appreciate that the steps of the processes discussed herein may be omitted, modified, combined and/or rearranged, and any additional steps may be performed without departing from the scope of the invention. More generally, the above disclosure is meant to be exemplary and not limiting. Only the claims that follow are meant to set bounds as to what the present invention includes. Furthermore, it should be noted that the features and limitations described in any one embodiment may be applied to any other embodiment herein, and flowcharts or examples relating to one embodiment may be combined with any other embodiment in a suitable manner, done in different orders, or done in parallel. In addition, the systems and methods described herein may be performed in real time. It should also be noted that the systems and/or methods described above may be applied to, or used in accordance with, other systems and/or methods.

1. A method comprising:
playing, via a computing device in a media presentation environment, audio content at a first output volume level;
detecting a change in a number of users in the media presentation environment;
in response to the detecting the change in the number of users in the media presentation environment:
retrieving a stored output volume adjustment value corresponding to the detected change in the number of users in the media presentation environment; and
automatically adjusting the first output volume level to a second output volume level, based on the retrieved output volume adjustment value;
receiving a volume change request from a user in the media presentation environment to adjust the second output volume level to a third output volume level;
in response to the receiving the volume change request, adjusting the second output volume level to the third output volume level and determining whether the volume change request was received within a predetermined time after the automatically adjusting the first output volume level to the second output volume level; and
in response to determining that the volume change request was received within the predetermined time, updating the stored output volume adjustment value corresponding to the detected change in the number of users in the media presentation environment, based on a difference between the second output volume level and the third output volume level.

2. The method of claim 1, further comprising detecting noise in the media presentation environment,
wherein the automatically adjusting the first output volume level to the second output volume level is further based on the detected noise in the media presentation environment.

3. The method of claim 1, wherein the updating the stored output volume adjustment value corresponding to the detected change in the number of users in the media presentation environment comprises updating a plurality of stored output volume adjustment values, each corresponding to a respective change in a number of users in the media presentation environment, based on the difference between the second output volume level and the third output volume level, and
wherein the stored output volume adjustment value corresponding to the detected change in the number of users in the media presentation environment is one of the plurality of stored output volume adjustment values.

4. The method of claim 1, wherein when the detected change in the number of users in the media presentation environment is an increase in the number of users, the automatically adjusting the first output volume level to the second output volume level comprises increasing the first output volume level to the second output volume level.

5. The method of claim 1, wherein when the detected change in the number of users in the media presentation environment is a decrease in the number of users, the automatically adjusting the first output volume level to the second output volume level comprises decreasing the first output volume level to the second output volume level.

6. The method of claim 1, further comprising determining a user profile of a user in the media presentation environment,
wherein the updating the stored output volume adjustment value corresponding to the change in the number of users in the media presentation environment comprises updating a stored output volume adjustment value in the determined user profile.

7. The method of claim 6, wherein the determined user profile is associated with the user from which the volume change request was received.

8. The method of claim 1, wherein when the third output volume level is less than the second output volume level, the updating the stored output volume adjustment value comprises decreasing the stored output volume adjustment value, and
wherein when the third output volume level is greater than the second output volume level, the updating the stored output volume adjustment value comprises increasing the stored output volume adjustment value.

9. The method of claim 1, further comprising:
in response to the automatically adjusting the first output volume level to the second output volume level, generating for output a notification that an output volume level has been changed based on the detected change in the number of users in the media presentation environment.

10. The method of claim 1, wherein the detecting the change in the number of users in the media presentation environment comprises detecting a first change in the number of users in the media presentation environment, and
wherein the method further comprises:
detecting a second change in the number of users in the media presentation environment; and
in response to the detecting the second change in the number of users in the media presentation environment:
retrieving the updated stored output volume adjustment value corresponding to the detected first change in the number of users in the media presentation environment; and
automatically adjusting the third output volume level to a fourth output volume level, based on the retrieved updated stored output volume adjustment value.

11. A system comprising control circuitry configured to:
play, via a computing device in a media presentation environment, audio content at a first output volume level;
detect a change in a number of users in the media presentation environment;
in response to the detecting the change in the number of users in the media presentation environment:
retrieve a stored output volume adjustment value corresponding to the detected change in the number of users in the media presentation environment; and
automatically adjust the first output volume level to a second output volume level, based on the retrieved output volume adjustment value;
receive a volume change request from a user in the media presentation environment to adjust the second output volume level to a third output volume level;
in response to the receiving the volume change request, adjust the second output volume level to the third output volume level and determine whether the volume change request was received within a predetermined time after the automatically adjusting the first output volume level to the second output volume level; and
in response to determining that the volume change request was received within the predetermined time, update the stored output volume adjustment value corresponding to the detected change in the number of users in the media presentation environment, based on a difference between the second output volume level and the third output volume level.

12. The system of claim 11, wherein the control circuitry is further configured to detect noise in the media presentation environment, and
wherein the control circuitry is further configured, when automatically adjusting the first output volume level to the second output volume level, to automatically adjust the first output volume level to the second output volume level further based on the detected noise in the media presentation environment.

13. The system of claim 11, wherein the control circuitry is further configured, when updating the stored output volume adjustment value corresponding to the detected change in the number of users in the media presentation environment, to update a plurality of stored output volume adjustment values, each corresponding to a respective change in a number of users in the media presentation environment, based on the difference between the second output volume level and the third output volume level, and
wherein the stored output volume adjustment value corresponding to the detected change in the number of users in the media presentation environment is one of the plurality of stored output volume adjustment values.

14. The system of claim 11, wherein when the detected change in the number of users in the media presentation environment is an increase in the number of users, the control circuitry is further configured, when automatically adjusting the first output volume level to the second output volume level, to increase the first output volume level to the second output volume level.

15. The system of claim 11, wherein when the detected change in the number of users in the media presentation environment is a decrease in the number of users, the control circuitry is further configured, when automatically adjusting the first output volume level to the second output volume level, to decrease the first output volume level to the second output volume level.

16. The system of claim 11, wherein the control circuitry is further configured to determine a user profile of a user in the media presentation environment, and
wherein the control circuitry is further configured, when updating the stored output volume adjustment value corresponding to the change in the number of users in the media presentation environment, to update a stored output volume adjustment value in the determined user profile.

17. The system of claim 16, wherein the determined user profile is associated with the user from which the volume change request was received.

18. The system of claim 11, wherein when the third output volume level is less than the second output volume level, the control circuitry is further configured, when updating the stored output volume adjustment value, to decrease the stored output volume adjustment value, and
wherein when the third output volume level is greater than the second output volume level, the control circuitry is further configured, when updating the stored output volume adjustment value, to increase the stored output volume adjustment value.

19. The system of claim 11, wherein the control circuitry is further configured to:
in response to the automatically adjusting the first output volume level to the second output volume level, generate for output a notification that an output volume level has been changed based on the detected change in the number of users in the media presentation environment.

20. The system of claim 11, wherein the control circuitry is further configured, when detecting the change in the number of users in the media presentation environment, to detect a first change in the number of users in the media presentation environment, and
wherein the control circuitry is further configured to:
detect a second change in the number of users in the media presentation environment; and
in response to the detecting the second change in the number of users in the media presentation environment:
retrieve the updated stored output volume adjustment value corresponding to the detected first change in the number of users in the media presentation environment; and
automatically adjust the third output volume level to a fourth output volume level, based on the retrieved updated stored output volume adjustment value.

21.-30. (canceled)
